(19) United States
(12) Patent Application Publication
(10) Pub. No.: US 2026/0120997 A1
(43) Pub. Date: Apr. 30, 2026

(54) PLASMA ASSISTED REMEDIATION OF SINGLE CRYSTAL DIAMOND SURFACES

(71) Applicant: The Government of the United States of America, as represented by the Secretary of the Navy, Arlington, VA (US)

(72) Inventors: Bradford B. Pate, Arlington, VA (US); Michael A. Mathews, JR., Alexandria, VA (US); Jonathan B. Levine-Miles, Silver Spring, MD (US)

(73) Assignee: The Government of the United States of America, as represented by the Secretary of the Navy, Arlington, VA (US)

(21) Appl. No.: 19/376,286

(22) Filed: Oct. 31, 2025

Related U.S. Application Data
(60) Provisional application No. 63/714,572, filed on Oct. 31, 2024.

(51) Int. Cl. H01J 37/32

(52) U.S. Cl. CPC H01J 37/321; H01J 2237/3341

(57) ABSTRACT

A method of remediation of single crystal diamond surfaces by: mounting a single crystal diamond seed to a quartz or sapphire substrate, performing a first reactive ion etch from an inductively coupled first plasma on the seed, optionally performing a first rapid thermal anneal on the seed under hydrogen and a first inert gas, performing a second reactive ion etch from an inductively coupled second plasma on the seed, and optionally performing a second rapid thermal anneal on the seed under hydrogen and a second inert gas. The first plasma is an SF₆ plasma and has first ion energies from 200 to 300 eV. The second plasma is an SF₆ plasma or a hydrogen/inert gas plasma and has second ion energies below 40 eV.

### REFERENCE TO RELATED APPLICATIONS

This application claims the benefit of U.S. Provisional Application No. 63/714,572 filed on Oct. 31, 2024. The provisional application and all other publications and patent documents referred to throughout this nonprovisional application are incorporated herein by reference.

### TECHNICAL FIELD

The present disclosure is generally related to remediation of single crystal diamond surfaces.

### DESCRIPTION OF THE RELATED ART

Chemical vapor deposited (CVD) single crystal diamond is grown from single crystal diamond seeds. These seeds are cleaned and mechanically polished before initiating epitaxial growth. Mechanical polishing induces lattice damage that is sub-surface in the diamond seed, typically in the form of threading dislocations and stacking faults. If left untreated, these defects then propagate into homo-epitaxial material during growth, which limit crystal quality and subsequently impacts device characteristics.

Before deposition (growth) of large single crystal diamond from seeds, mechanical polishing damage on the seed is typically removed by a relatively harsh hydrogen plasma etch in the diamond plasma CVD reactor just before initiation of growth. Such a hydrogen plasma etch often leads to non-planar and rough surfaces.

In contrast to bulk material growth, deposition of thin film epitaxial layers of diamond (for example, device layers) may be required. Deposition of high-quality thin film epitaxial diamond requires removal of buried damage while maintaining the planarity and smoothness of the surface during etch, while not imparting damage. In addition, methods to produce 3D structures (e.g. trenches) may be required without otherwise imparting damage to the exposed diamond surfaces.

### SUMMARY OF THE INVENTION

Disclosed herein is a method comprising: mounting a single crystal diamond seed to a quartz or sapphire substrate, performing a first reactive ion etch from an inductively coupled first plasma on the seed, optionally performing a first rapid thermal anneal on the seed under hydrogen and a first inert gas, performing a second reactive ion etch from an inductively coupled second plasma on the seed, and optionally performing a second rapid thermal anneal on the seed under hydrogen and a second inert gas. The first plasma is an SF₆ plasma and has first ion energies from 200 to 300 eV. The second plasma is an SF₆ plasma or a hydrogen/inert gas plasma and has second ion energies below 40 eV.

### BRIEF DESCRIPTION OF DRAWINGS

A more complete appreciation will be readily obtained by reference to the following Description of the Example Embodiments and the accompanying drawings.

FIG. 1 shows an XPS spectrum of an initial diamond seed surface.

FIG. 2 shows an XPS spectrum of the diamond seed after performing a first reactive ion etch.

FIG. 3 shows an XPS spectrum of the diamond seed after performing a first rapid thermal anneal.

FIG. 4 shows an XPS spectrum of the diamond seed after performing a second reactive ion etch.

FIG. 5 shows an XPS spectrum of the diamond seed after performing a second rapid thermal anneal.

### DETAILED DESCRIPTION

In the following description, for purposes of explanation and not limitation, specific details are set forth in order to provide a thorough understanding of the present disclosure. However, it will be apparent to one skilled in the art that the present subject matter may be practiced in other embodiments that depart from these specific details. In other instances, detailed descriptions of well-known methods and devices are omitted so as to not obscure the present disclosure with unnecessary detail.

Disclosed herein is a method to provide a surface preparation technique to enable higher quality homoepitaxial growth of single crystal diamond by creating an atomically smooth surface, and maintaining a planar surface, while remediating (removing) damage buried within the single crystal diamond surface that arises from mechanical polishing. The method is also described in Mathews et al., “Fluorine plasma-assisted remediation of single crystal diamond surfaces” J. Vac. Sci. Technol. A 43, 043009 (2025), incorporated herein by reference.

Homoepitaxial growth of CVD single crystal diamond is known to depend on the surface of the prepared diamond seed. These surfaces are prepared by mechanical polishing on a cast iron (Scaife) wheel with diamond grit. Mechanical stresses from diamond chipping away diamond are known to induce sub-surface damage in the diamond seed. This damage can extend from as little as hundreds of nanometers to 10 microns into the diamond seed. This surface is also grooved. This induces both defect propagation (from threading dislocations and stacking faults) into newly grown epi-layers along with a strain from growth on the prepared surface. Herein is demonstrate a method using the ion energy control intrinsic to reactive ion etch from an inductively coupled plasma (ICP-RIE) to both remove buried damage from mechanical polishing, as well as provide an atomically smooth planar surface for higher quality diamond chemical vapor deposition.

First, a single crystal diamond seed is mounted to a quartz or sapphire substrate. The mounting can be by any means that secures the seed to the substrate during the disclosed method, while allowing the seed to be non-destructively removed from the substrate afterwards. One suitable method is a halogen- and silicon-free vacuum grease. The use of quartz or sapphire helps to control the DC bias during ICP-RIE.

In a first processing step, a first reactive ion etch from an inductively coupled first plasma is performed on the seed using an SF₆ plasma having ion energies from 200 to 300 eV. This step may achieve etch rates of 15-22 nm/min while reducing the root mean square surface roughness by 20-40% or an areal rms roughness (Sq) of no more than 0.5 nm. A typical Sq is 0.3 to 0.5 nm roughness (measured by AFM). This is measured after 10 microns of removal, and after the first rapid thermal anneal (RTA). Sq is the square root of the average of the squared height deviations. Sq is measured over a minimum 5 μm×5 μm area. The first etch may be performed until a thickness of the seed is reduced by at least 0.5 μm or, for example, 5-10 μm. The actual thickness reduction may be determined by the depth of any damage in the seed.

In a second processing step, a first rapid thermal anneal is performed on the seed under hydrogen and a first inert gas. The first anneal may have a maximum temperature of 900° C. and may be performed under argon. This step removes fluorine and other non-diamond molecular components that may remain on the surface after the first etch. It allows for accurate AFM measurement after the first etch. This step is optional and may not be required to achieve the final roughness measurement after second plasma etch.

In a third processing step, a second reactive ion etch from an inductively coupled second plasma is performed on the seed using an SF₆ plasma or a hydrogen/inert gas plasma having ion energies below 40 eV. The hydrogen/inert gas plasma may be a hydrogen/argon plasma. The second etch may reduce a thickness of the seed by at least 100 nm and achieve Sq of no more than 0.3 nm. Typical Sq is 0.08 to 0.3 nm roughness (measured by AFM). This is after 100 nm of removal and is measured with AFM after the second RTA.

In a fourth processing step, a second rapid thermal anneal is performed on the seed under hydrogen and a second inert gas. The second anneal may have a maximum temperature of 900° C. and may be performed under argon. As above, this step removes fluorine and other non-diamond molecular components that may remain on the surface after the first etch and allows for accurate AFM measurement after the second etch. This step is optional and may not be required depending on subsequent processing (e.g. hot acid cleaning).

After all etching and any rapid thermal annealing, additional diamond may be grown on the seed by chemical vapor deposition. Such methods are known in the art.

Potential advantages of this method include:
1) An atomically smooth (root mean square roughness <0.5 nm and can reach <0.1 nm), planar diamond seed surface, which is easier to grow on and reduces strain in the grown epi-layers.
2) The ability to remove buried damage in both high and lower quality diamond seeds.
3) The removal of ion-induced damage from ion bombardment in the material through the low dc bias chemical plasma etch (second etch).
4) It allows for a follow-up process to mechanical polishing for removal of buried polishing damage, to produce a high-quality growth surface.
5) It provides for high quality diamond at photonically or electronically critical regions near surfaces or near interfaces between layers.

The following examples are given to illustrate specific applications. These specific examples are not intended to limit the scope of the disclosure in this application.

Four-step process—The single crystal diamond seed is mounted onto a quartz carrier wafer (a quartz carrier wafer helps control the DC bias, especially at lower ion energies, since quartz is significantly more insulating than silicon) using a halogen- and silicon-free vacuum grease before being lock-loaded into an ICP-RIE at a pressure of 10-20 mTorr. The first process step is to expose this seed to a SF₆ plasma with DC bias (ion energies) ranging from 200-300 eV. Etch rates of 15-22 nm/min are achieved under Step 1 conditions. Furthermore, Step 1 reduces the root mean square surface roughness by 20-40%.

This surface, having been fluorinated by Step 1, is subjected to Step 2, a rapid thermal anneal (RTA) in a reducing atmosphere comprised of 3% H₂ in an inert gas (e.g., argon) at a pressure of 10 mTorr. The RTA thermal ramp begins from room temperature at a rate of 7° C./s until 200° C. (warmup step) is reached. At 200° C. the ramp rate is increased to 15° C./s until 900° C. is reached. The sample then dwells at 900° C. for anywhere from 90-120 s. Step 2 both desorbs and volatilizes fluorine-based species as well as reducing some surface oxygen and non-diamond carbon contaminants.

While Step 1 employs sputtering from high-energy ions in order to remove material at a desirable and rapid etch rate, the high-energy ions also induce undesirable near-surface lattice damage. Step 3 is designed to remedy the near surface lattice damage from energetic ions. Step 3, which uses either SF₆ or 5% H₂ in an inert gas (e.g., argon) plasma but at a sufficiently low ion energy such that it is below the sputter threshold of diamond (45 eV). Step 3 has a considerably lower etch rate (0.7 nm/min) and is used to remove material on the order of nanometers. Step 3 is thereby applied to remove near surface material damaged by the energetic ion bombardment (sputtering) of Step 1. After Step 3, the surface is processed in Step 4 using the same rapid thermal annealing atmosphere and conditions as Step 2. After the 4-Step process and with a clean surface, atomic force microscopy showed a marked improvement of surface smoothness with a 60% reduction in root mean square surface roughness (5 μm×5 μm scan size). X-ray photoelectron spectroscopy also showed an improvement by narrowing of the diamond peak in the carbon 1 s spectrum, which signifies a higher degree of order within the crystal. In principle, a repeat of the Step 1 through Step 4 process would continue to lower roughness while removing buried damage in the diamond surface.

Occasionally, surfaces processed using the SF₆ chemical etch described in step three showed surfaces that had agglomerated non-diamond carbon particles left behind after the rapid thermal anneal (step four). These were removed by etching for an hour in piranha solution (3:1 H₂SO₄:H₂O₂) and a gentle treatment in a low energy O₂ plasma asher for 120 s.

Hydrogen chemical etching as an alternative to Step 3 fluorine-based chemical plasma etching—Although the process was envisioned as utilizing SF₆ for the low ion energy chemical etch (Step 3), it was found that 5% H₂ in an inert gas (e.g., argon) plasma (at ion energies below the sputtering threshold of diamond) had the same etch rate as the SF₆ chemical etch described in Step 3 above and continued to smooth the surface. Furthermore, this alternative plasma etch effectively removes fluorine-based species by chemical reduction and partially hydrogenates the surface. Surface hydrogenation was shown to mostly remain even after anneals Step 4 anneals (described above).

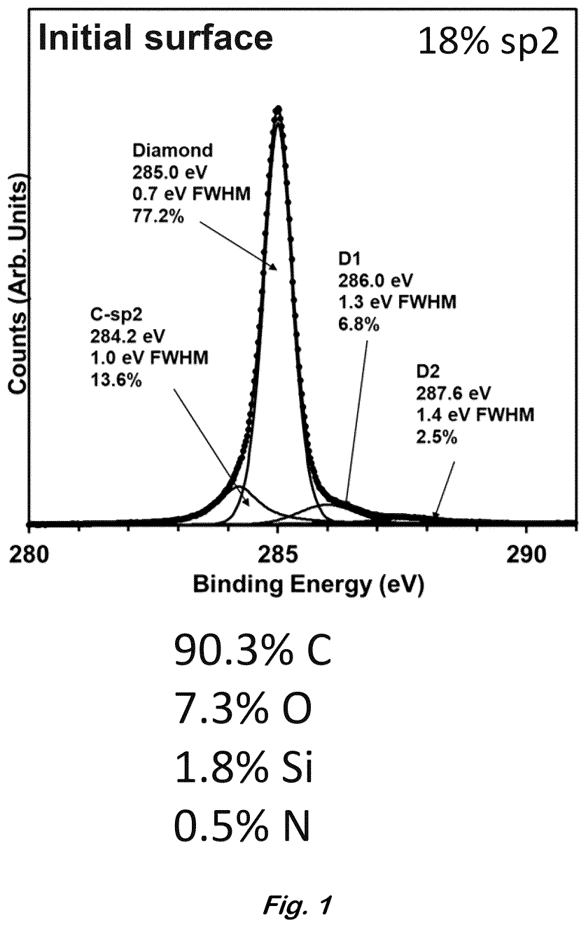

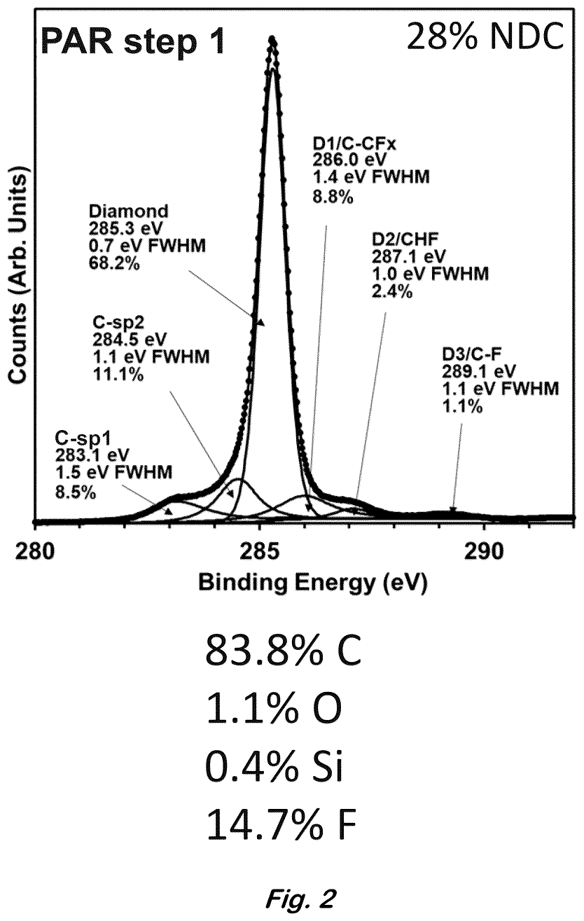

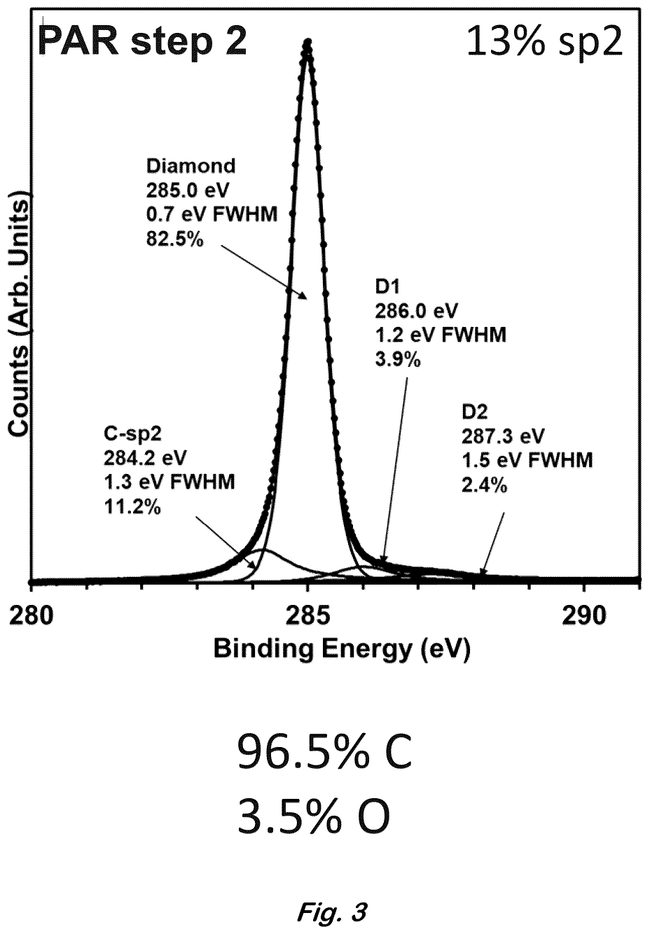

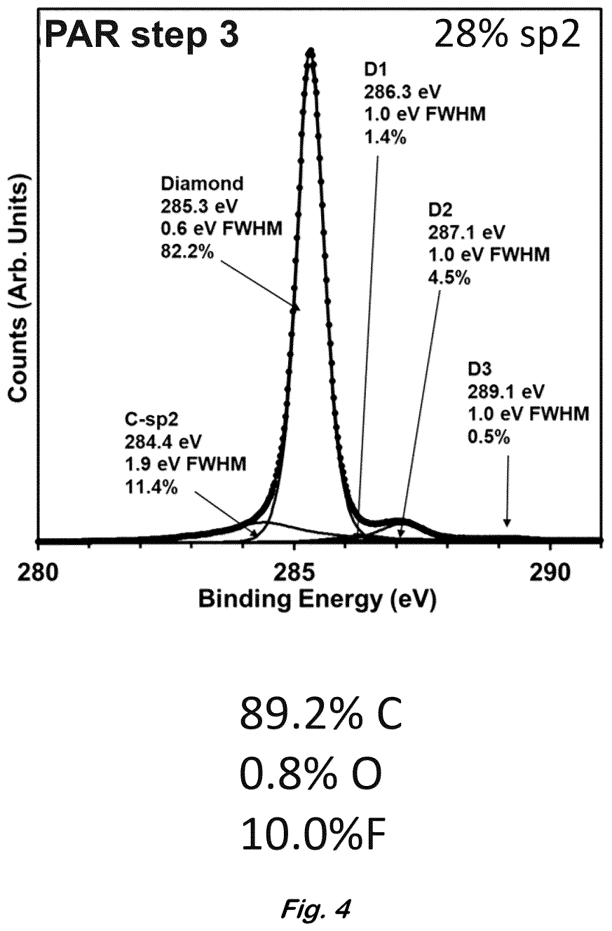

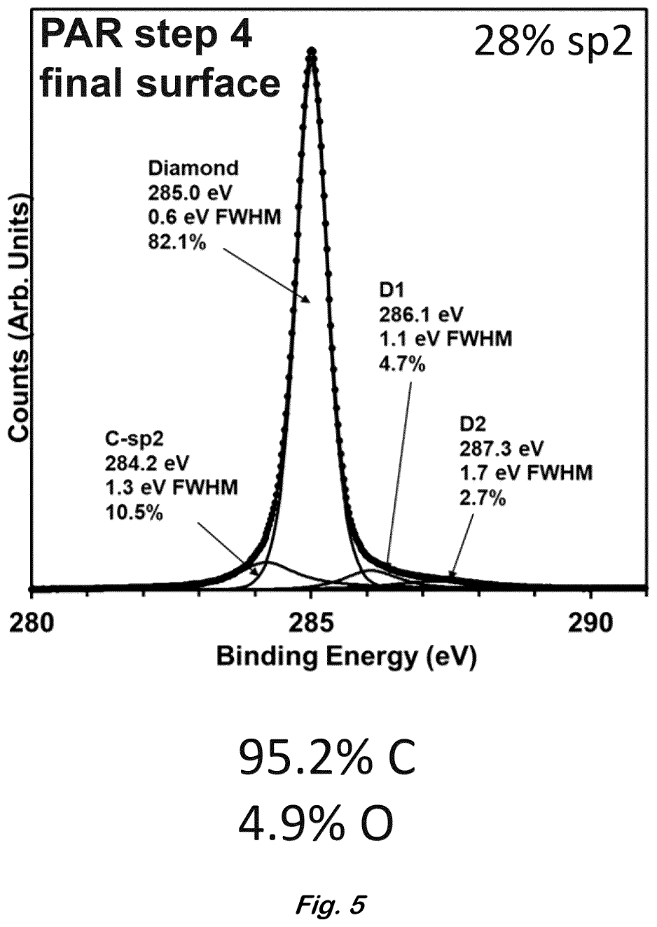

Materials characterization—Single crystal diamond surface chemistry was monitored using x-ray photoelectron spectroscopy (XPS). XPS data was acquired using a NEXSA XPS system from ThermoFisher Scientific. XPS confirmed the chemical states of the surface as well as narrowing of peaks after using the process (FIGS. 1-5). Atomic force microscopy (AFM) was used to assess the morphology of the surface before and after each step of the process. AFM images were acquired using a Bruker Dimension FastScan AFM using triangular tips with a nominal tip radius of 5 nm which confirmed the increasing surface smoothness as the process progressed through each step.

Many modifications and variations are possible in light of the above teachings. It is therefore to be understood that the claimed subject matter may be practiced otherwise than as specifically described. Any reference to claim elements in the singular, e.g., using the articles “a”, “an”, “the”, or “said” is not construed as limiting the element to the singular.

What is claimed is:

1. A method comprising:
mounting a single crystal diamond seed to a quartz or sapphire substrate;
performing a first reactive ion etch from an inductively coupled first plasma on the seed;
wherein the first plasma is an SF₆ plasma; and
wherein the first plasma has first ion energies from 200 to 300 eV;
optionally, performing a first rapid thermal anneal on the seed under hydrogen and a first inert gas;
performing a second reactive ion etch from an inductively coupled second plasma on the seed;
wherein the second plasma is an SF₆ plasma or a hydrogen/inert gas plasma; and
wherein the second plasma has second ion energies below 40 eV; and
optionally, performing a second rapid thermal anneal on the seed under hydrogen and a second inert gas.

2. The method of claim 1, wherein the first etch reduces a thickness of the seed by at least 0.5 μm.

3. The method of claim 1, wherein the first anneal has a maximum temperature of 900° C.

4. The method of claim 1, wherein the first inert gas is argon.

5. The method of claim 1, wherein the second etch reduces a thickness of the seed by at least 100 nm.

6. The method of claim 1, wherein the hydrogen/inert gas plasma is a hydrogen/argon plasma.

7. The method of claim 1, wherein the second anneal has a maximum temperature of 900° C.

8. The method of claim 1, wherein the second inert gas is argon.

9. The method of claim 1, further comprising:
performing chemical vapor deposition of diamond onto the seed after the second etch or the second rapid thermal anneal.
